(19) United States
(12) Patent Application Publication
(10) Pub. No.: US 2023/0208279 A1
(43) Pub. Date: Jun. 29, 2023

(54) ACTIVE DIODE CIRCUIT AND AC/DC POWER CONVERSION CIRCUIT

(71) Applicant: SHENZHEN HUNTKEY ELECTRIC CO., LTD., Shenzhen (CN)

(72) Inventor: Weiyin DUAN, Shenzhen (CN)

(21) Appl. No.: 16/982,538

(22) PCT Filed: Jul. 29, 2020
(86) PCT No.: PCT/CN2020/105555

§ 371 Date: Feb. 27, 2023

(30) Foreign Application Priority Data
Jul. 29, 2019 (CN) 201910688008.4

(51) Int. Cl. H02M 1/32; H02M 1/42; H02M 1/36; H02M 7/219; H02M 1/00

(52) U.S. Cl. CPC H02M 1/32; H02M 1/36; H02M 1/0085; H02M 1/4233; H02M 7/219

(57) ABSTRACT

The present application relates to the field of electronic technology and provides an active diode circuit and an AC/DC power conversion circuit, including a power interface, a drain interface, a control interface, a source interface, a logic unit, a constant current source, and a first switch transistor. A first terminal of the constant current source is connected to the drain interface of the active diode circuit, a second terminal and a third terminal of the constant current source are both connected to the power interface, and a fourth terminal of the constant current source is connected to the logic unit; a first input terminal of the logic unit is connected to the fourth terminal of the constant current source, a second input terminal of the logic unit is connected to the control interface, and an output terminal of the logic unit is connected to a gate electrode of the first switch transistor; and the drain electrode of the first switch transistor is connected to the drain interface of the active diode circuit, and the source electrode of the first switch transistor is connected to the source interface of the active diode circuit. The present application solves the problems of the diode temperature rise of the rectifier bridge and the complex structure of the PFC circuit.

### TECHNICAL FIELD

The present application relates to the field of electronic technology, and particularly to an active diode circuit and an AC-DC power conversion circuit.

### BACKGROUND

The commonly used bridge rectifying circuit is composed of diodes, and the circuit rectifies alternating current (AC) into direct current (DC). The diode rectifier bridge has the disadvantages of low efficiency and increased temperature. In the design of power adapters and chargers, the diode rectifier bridge is the device with the highest temperature, which can cause the plastic shell to dissolve or soften.

PFC (Power Factor Correction) circuit is usually set at the input terminal of the switching power supply to improve the power factor of the power supply, eliminate high-order harmonics, and reduce the loss of the electric grid. With improved energy efficiency standards for power converters, many schemes of bridgeless PFC have been adopted in industry. As shown in FIG. 1, a diode rectifier bridge is provided at the input terminal, and the power factor correction circuit is composed of a Boost circuit. Active switching devices, such as MOSFET and GaN, are used in the rectifying circuit. The number of PFC inductors increases, and the use of dual inductors increases the system volume. In the control and protection circuit, more separation devices are used.

### TECHNICAL PROBLEMS

In view of the above, the embodiments of the present application provide an active diode circuit and an AC/DC power conversion circuit, so as to solve the problems of the diode temperature rise of the rectifier bridge and the complex structure of the PFC circuit.

### TECHNICAL SOLUTIONS

A first aspect of the embodiments of the present application provides an active diode circuit, including a power interface, a drain interface, a control interface, a source interface, a logic unit, a constant current source, and a first switch transistor;
the constant current source is provided with a first terminal, a second terminal, a third terminal and a fourth terminal, the first terminal being connected to the drain interface of the active diode circuit, the second terminal and the third terminal both being connected to the power interface, and the fourth terminal being connected to the logic unit; and the constant current source is configured to provide a constant current for the power interface when a voltage input from the drain interface of the active diode circuit charges the power interface;
the logic unit is provided with a first input terminal, a second input terminal and an output terminal, the first input terminal being connected to the fourth terminal of the constant current source, the second input terminal being connected to the control interface, and the output terminal being connected to a gate electrode of the first switch transistor; and the logic unit is configured to:
   monitor whether a parasitic body diode of the first switch transistor is in conduction state, that is, whether a voltage difference between a source electrode and a drain electrode of the first switch transistor is greater than a conducting voltage of the body diode,
   receive a PWM signal input from the control interface as a control signal for the first switch transistor, if the body diode is in non-conduction state; and
   shield the PWM signal input from the control interface and output an electric level signal to control the first switch transistor to be in conduction state, if the body diode is in conduction state;
   the drain electrode of the first switch transistor is connected to the drain interface of the active diode circuit, and the source electrode of the first switch transistor is connected to the source interface of the active diode circuit.

A second aspect of the embodiments of the present application provides an AC / DC power conversion circuit, including an AC voltage positive input terminal, an AC voltage negative input terminal, a DC voltage output terminal, a reference ground terminal, a PFC controller, a first capacitor, a second capacitor, a third capacitor, a fourth capacitor, a common-differential mode inductor, a third diode, a fourth diode, and two above-said active diode circuits;
the PFC controller is configured to output a PFC control signal on the basis of a sampling voltage of the DC voltage output terminal and a sampling current of the common-differential mode inductor;
the first capacitor is connected in series between the AC voltage positive input terminal and the AC voltage negative input terminal;
the second capacitor is connected in series between the DC voltage output terminal and the reference ground terminal;
the common-differential mode inductor is provided with a primary winding and a secondary winding, a positive terminal of the primary winding is connected to the AC voltage positive input terminal, a negative terminal of the primary winding is connected to an anode of the third diode, a positive terminal of the secondary winding is connected to the AC voltage negative input terminal, a negative terminal of the secondary winding is connected to an anode of the fourth diode, a differential mode inductor of the common-differential mode inductor is configured for energy storage of a PFC circuit, and a common mode inductor of the common-differential mode inductor is configured to eliminate common-mode noise;
a drain interface of a first active diode circuit is connected to the anode of the third diode, a source interface of the first active diode circuit is connected to the reference ground terminal, a power interface of the first active diode circuit is connected to the reference ground terminal through the third capacitor, and a control interface of the first active diode circuit is connected to an output terminal of the PFC controller;
a drain interface of a second active diode circuit is connected to the anode of the fourth diode, a source interface of the second active diode circuit is connected to the reference ground terminal, a power interface of the second active diode circuit is connected to the reference ground terminal through the fourth capacitor, and a control interface of the second active diode circuit is connected to the output terminal of the PFC controller;
a cathode of the third diode and a cathode of the fourth diode are connected to the DC voltage output terminal.

A third aspect of the embodiments of the present application provides an AC / DC power conversion circuit, including an AC voltage positive input terminal, an AC voltage negative input terminal, a DC voltage output terminal, a reference ground terminal, a first capacitor, a second capacitor, a third capacitor, a fourth capacitor, a common-differential mode inductor, a third diode, a fourth diode, and two above-said active diode circuits;
the first capacitor is connected between the AC voltage positive input terminal and the AC voltage negative input terminal;
the second capacitor is connected between the DC voltage output terminal and the reference ground terminal;
the common-differential mode inductor is provided with a primary winding and a secondary winding; a positive terminal of the primary winding is connected to the AC voltage positive input terminal, a negative terminal of the primary winding is connected to an anode of the third diode; a positive terminal of the secondary winding is connected to the AC voltage negative input terminal, and a negative terminal of the secondary winding is connected to an anode of the fourth diode;
an input interface of a first active diode circuit is connected to the anode of the third diode, a ground interface of the first active diode circuit is connected to the reference ground terminal, a power interface of the first active diode circuit is connected to the reference ground terminal through the third capacitor, and a control interface of the first active diode circuit is connected to the reference ground terminal;
an input interface of a second active diode circuit is connected to the anode of the fourth diode, a ground interface of the second active diode circuit is connected to the reference ground terminal, a power interface of the second active diode circuit is connected to the reference ground terminal through the fourth capacitor, and a control interface of the second active diode circuit is connected to the reference ground terminal;
a cathode of the third diode and a cathode of the fourth diode are connected to the DC voltage output terminal.

### BENEFICIAL EFFECTS

The beneficial effects of the present application:

The present application designs an active diode circuit, by detecting the on/off state (conduction/non-conduction state) of the body diode of the first switch transistor, the first switch transistor is controlled to be in conduction state or non-conducive to realize unidirectional conduction, so as to rectify the alternating current. Compared with diode, the switch transistor has the characteristics of low conduction loss, which can effectively reduce the conduction loss and the overall temperature rise of the circuit in specific application circuits.

The present application combines the inductor involved in the circuit for realizing the PFC function in the prior art with the common-differential mode inductor at the input terminal, at the same time, the switching device and diode for the PFC are incorporated into the rectifying circuit, i.e. the active diode circuit. Both the function of rectification and the function of receiving PFC control can be realized. The present application reduces separation devices, simplifies the controller of the PFC circuit, improves the power density of the AC/DC power conversion circuit, and improves the efficiency of the rectifying circuit and the power correction circuit.

### BRIEF DESCRIPTION OF THE DRAWINGS

In order to more clearly explain the technical solutions in the embodiments of the present application, the drawings needed in the description of the embodiments or the prior art will be briefly introduced hereafter. Obviously, the drawings in the following description are only some embodiments of the present application, for those of ordinary skill in the art, other drawings may also be obtained based on these drawings without paying creative labor.

FIG. 1 is a circuit diagram of an AC-DC power conversion circuit in the prior art;

FIG. 2 is a schematic block diagram of an active diode circuit according to an embodiment of the present application;

FIG. 3 is a circuit diagram of an active diode circuit according to an embodiment of the present application;

FIG. 4 is an operating timing diagram of an active diode circuit according to an embodiment of the present application;

FIG. 5 is a circuit diagram of an AC-DC power conversion circuit according to an embodiment of the present application;

FIG. 6 is an operating timing diagram of an AC-DC power conversion circuit according to an embodiment of the present application;

FIG. 7 is a circuit diagram of an AC-DC power conversion circuit according to another embodiment of the present application;

FIG. 8 is a circuit diagram of a protection circuit according to an embodiment of the present application;

FIG. 9 is an operating timing diagram of a start-up surge protection of an AC-DC power conversion circuit according to an embodiment of the present application;

FIG. 10 is a circuit diagram of an AC-DC power conversion circuit according to yet another embodiment of the present application;

FIG. 11 is an operating timing diagram of a start-up surge and overvoltage protection of an AC-DC power conversion circuit according to an embodiment of the present application;

FIG. 12 is a circuit diagram of an AC-DC power conversion circuit according to still another embodiment of the present application.

In the figures: 100-constant current source; 200-logic unit.

### DETAILED DESCRIPTION

In order to enable those of ordinary skill in the art to better understand the solutions of the present application, the technical solutions in the embodiments of the present application will be clearly described below in combination with the accompanying drawings in the embodiments of the present application. Obviously, the described embodiments are just some embodiments of the present application, not all embodiments. Based on the embodiments of the present application, all other embodiments obtained by those of ordinary skill in the art without paying creative work shall fall within the protection scope of the present application.

The term “comprising/including” and any variations thereof in the specification and claims of the present application are intended to cover a non-exclusive inclusion. For example, a process, method, system, product, or device that includes a series of steps or units is not limited to the listed steps or units, but may optionally include unlisted steps or units, or may optionally include other steps or units inherent in this process, method, system, product or device.

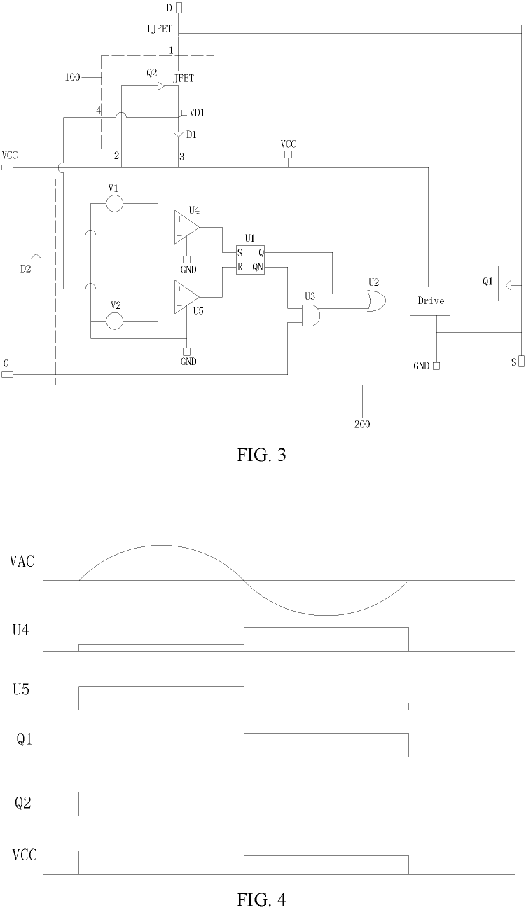

As shown in FIGS. 2-3, the active diode circuit includes a power interface VCC, a drain interface D of the active diode circuit, a control interface G, a source interface S of the active diode circuit, a logic unit 200, a constant current source 100, and the first switch transistor Q1. The first terminal of the constant current source 100 is connected to the drain interface D of the active diode circuit, the second terminal and the third terminal of the constant current source 100 are both connected to the power interface VCC, and the fourth terminal is connected to the logic unit 200. The constant current source 100 is configured to provide a constant current for the power interface VCC when the voltage input from the drain interface D of the active diode circuit charges the power interface VCC. The first input terminal of the logic unit 200 is connected to the fourth terminal VD1 of the constant current source 100, the second input terminal of the logic unit 200 is connected to the control interface G, and the output terminal of the logic unit 200 is connected to the gate of the first switch transistor Q1. The logic unit 200 is configured to monitor whether the parasitic body diode of the first switch transistor Q1 is in conduction state, that is, the whether the voltage difference between the source electrode and the drain electrode of the first switch transistor Q1 is greater than the conducting voltage of the body diode, if not, the body diode is in non-conduction state, the PWM (Pulse Width Modulation) signal input from the control interface G is received and used as the control signal for the first switch transistor Q1; if it is, the body diode is in conduction state, the PWM signal input from the control interface G is shielded, and an electric level signal is output, the electric level signal is high or low, and the first switch transistor Q1 is controlled to be in conduction state. The drain electrode of the first switch transistor Q1 is connected to the drain interface D of the active diode circuit, and the source electrode of the first switch transistor Q1 is connected to the source interface S of the active diode circuit.

When the constant current source 100 is in conduction state, the voltage at the sampling point VD1 of the logic unit 200 is approximately equal to the drain voltage of the first switch transistor Q1, and the source electrode of the first switch transistor Q1 is grounded, so the voltage collected by the logic unit 200 is the voltage difference between the drain voltage and the source voltage of the first switch transistor Q1. The constant current source 100 can be connected with an external energy storage capacitor through the power interface VCC. The logic unit 200 collects the drain voltage of the first switch transistor Q1, receives the PWM signal through the control interface G, and outputs control signal for the first switch transistor Q1, such that the conduction or non-conduction between the drain electrode and source electrode of the first switch transistor Q1 can be realized according to control signal for the first switch transistor Q1. When the active diode circuit is operating, the drain electrode of the first switch transistor Q1 is connected with an external AC power through the drain interface D of the active diode circuit. Through the conduction or non-conduction between the drain electrode and source electrode of the first switch transistor Q1, the alternating current can be rectified. Compared with the diode, the MOS switch transistor used in this circuit has the characteristics of low conducting resistance, which can effectively reduce the temperature rise in specific application circuits.

As shown in FIG. 3, the logic unit 200 includes a first comparator U4, a second comparator U5, a first RS flip-flop U1, and an OR gate U2, and the source interface of the active diode circuit is grounded.

The first comparator U4 is configured to receive the drain voltage of the first switch transistor Q1 through the constant current source 100, and compare the drain voltage of the first switch transistor Q1 with a first reference voltage to output a first signal. The first reference voltage can be provided by the first reference circuit V1, and the first reference circuit V1 can be correspondingly designed according to actual requirements to output the required first reference voltage.

The second comparator U5 is configured to receive the drain voltage of the first switch transistor Q1 through the constant current source 100, and compare the drain voltage of the first switch transistor Q1 with a second reference voltage to output a second signal. The second reference voltage can be provided by the second reference circuit V2, and the second reference circuit V2 can be correspondingly designed according to actual requirements to output the required second reference voltage.

The first RS flip-flop U1 is configured to output and latch a third signal on the basis of the first signal and the second signal.

The OR gate U2 is configured to perform OR logic on the third signal and the PWM signal, and output the control signal for the first switch transistor Q1. If the third signal is at a high electric level, the PWM signal is shielded at this time, the control signal for the first switch transistor Q1 is at a high electric level, and the first switch transistor Q1 is controlled to be in conduction state; if the third signal is at a low electric level, the PWM signal is provided as the control signal for the first switch transistor Q1 at this time, and the first switch transistor Q1 is controlled to be in conduction or non-conduction state on the basis of the PWM signal.

In an embodiment, the logic unit 200 further includes a first AND gate U3. The first AND gate U3 is configured to perform AND logic on the NOT-signal of the third signal and the PWM signal, and output a fourth signal. The OR gate U2 is configured to perform OR logic on the third signal and the fourth signal, and output the control signal for the first switch transistor Q1.

When the third signal is at a high electric level, the control signal for the first switch transistor Q1 output through the OR gate U2 is at a high electric level, at this time, the gate electrode of the first switch transistor Q1 receives the high electric level, and the source electrode and drain electrode of the first switch transistor Q1 are in conduction state. When the third signal is at a low electric level, AND logic is performed on the NOT-signal of the third signal and the PWM signal, thus the output fourth signal is the PWM signal, after performing OR logic on the fourth signal and the third signal, the control signal of the switch transistor Q1, that is the PWM signal, is output, and at this time the PWM signal is provided as the control signal for the first switch transistor Q1.

In an embodiment, the logic unit 200 further includes a first driver Drive. The first driver Drive, connected in series between the gate electrode of the first switch transistor Q1 and the OR gate U2, is configured to add a drive for the control signal for the first switch transistor Q1, so as to ensure that the control signal for the first switch transistor Q1, after passing through the first driver Drive, can drive the first switch transistor Q1 to be in conduction or non-conduction state.

In an embodiment, the active diode circuit further includes a first diode D1. The anode of the first diode D1 is respectively connected to the third terminal of the constant current source 100 and the first input terminal of the logic unit 200. The cathode of the first diode D1 is connected to the power interface VCC.

The constant current source 100 is connected to an external power supply or energy storage capacitor, and charges the power interface VCC of the active diode circuit through the third interface. When charging, the first diode D1 is in the conduction state and can charge the power interface VCC. When not charging, the first diode D1 can prevent the current from back flowing, thereby ensuring the sufficient energy of the power interface VCC.

In an embodiment, the constant current source 100 includes a first diode D1 and a second switch transistor Q2. The second switch transistor Q2 is provided as a depletion-type MOS transistor or JFET transistor. The drain electrode of the second switch transistor Q2 is provided as the first terminal of the constant current source 100, the source electrode of the second switch transistor Q2 is connected to the anode of the first diode D1, and a gate electrode of the second switch transistor Q2 is provided as the second terminal of the constant current source 100. The cathode of the first diode D1 is provided as the third terminal of the constant current source 100.

Either a depletion-type MOS transistor or a depletion-type JFET transistor can be used for the constant current source 100 to provide a stable current for charging the power interface VCC of the active diode circuit.

In an embodiment, the active diode circuit further includes a second diode D2, the anode of the second diode D2 is connected to the control interface G, and the cathode of the second diode D2 is connected to the power interface VCC.

The control interface G in the active diode circuit is connected to a PFC controller. While inputting the control signal through the control interface G, the PFC controller can also charge the power interface VCC to solve the problem of insufficient energy of the power interface VCC.

In an embodiment, the timing of the active diode circuit is shown as FIG. 4, at this time, the PWM signal received by the control interface G of the active diode circuit is at a low electric level, that is, the active diode is only used as a diode:

(1) When the AC voltage VAC input from the drain interface D of the active diode circuit is in a positive half cycle, the constant current source 100 provides a constant current to charge the external capacitor connected to the power interface VCC, and the voltage of the power interface VCC is a high electric level. At this time VD1>0, the parasitic body diode is in non-conduction state, the first comparator U4 outputs a low electric level, the second comparator U5 outputs a high electric level, the Q interface of the first RS flip-flop U1 outputs a low electric level, the QN interface outputs a high electric level, the first AND gate U3 outputs a low electric level, the OR gate U2 outputs a low electric level, and the low electric level output by the OR gate U2 passes through the first driver Drive as a control signal for the first switch transistor Q1 to control the first switch transistor Q1 to be in non-conduction state, that is, the drain interface D of the active diode circuit and the source interface S of the active diode circuit are not conducting.

(2) When the AC voltage VAC input from the drain interface D of the active diode circuit is in a negative half cycle, the constant current source 100 will no longer charge the power interface VCC, since the power interface VCC is connected with the external capacitor, the capacitor discharges at this time, and the voltage of the power interface VCC is also a high electric level, but slightly lower than the voltage when VAC is in the positive half cycle. At this time, VD1<0, VD1 continues to decrease until the parasitic body diode is in conduction state, the first comparator U4 outputs a high electric level, the second comparator U5 outputs a low electric level, the Q interface of the first RS flip-flop U1 outputs a high electric level, the QN interface outputs a low electric level, the first AND gate U3 outputs a low electric level, the OR gate U2 outputs a high electric level, and the high electric level output by the OR gate U2 passes through the first driver Drive as a control signal for the first switch transistor Q1 to control the first switch transistor Q1 to be in conduction state.

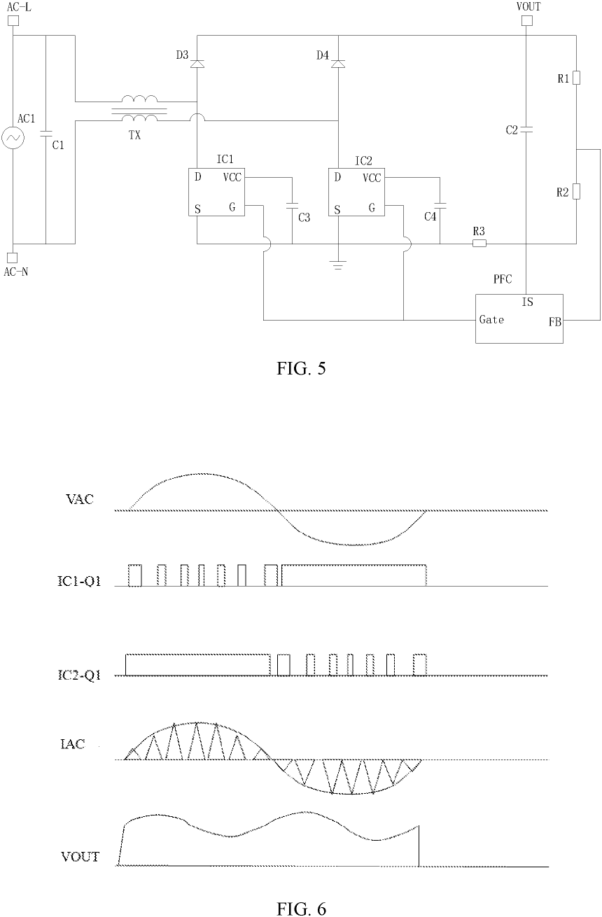

As shown in FIG. 5, the present application discloses an AC-DC power conversion circuit, which includes an AC voltage positive input terminal, an AC voltage negative input terminal, a DC voltage output terminal, a reference ground terminal, a PFC controller, a first capacitor C1, a first capacitor C1, a second capacitor C2, a third capacitor C3, a fourth capacitor C4, a common-differential mode inductor, a third diode D3, a fourth diode D4, and two above-said active diode circuits. The PFC controller is configured to output a PFC control signal on the basis of the sampling voltage of the DC voltage output terminal and the sampling current of the common-differential mode inductor. The first capacitor is connected in series between the AC voltage positive input terminal and the AC voltage negative input terminal. The second capacitor C2 is connected in series between the DC voltage output terminal and the reference ground terminal. The positive terminal of the primary winding of the common-differential mode inductor is connected to the AC voltage positive input terminal, the negative terminal of the primary winding of the common-differential mode inductor is connected to the anode of the third diode D3, the positive terminal of the secondary winding of the common-differential mode inductor is connected to the AC voltage negative input terminal, the negative terminal of the secondary winding of the common-differential mode inductor is connected to the anode of the fourth diode D4, the differential mode inductor of the common-differential mode inductor is configured for energy storage of the PFC circuit, and the common mode inductor of the common-differential mode inductor is configured to eliminate common-mode noise. The drain interface D of a first active diode circuit IC1 is connected to the anode of the third diode D3, the source interface S of the first active diode circuit IC1 is connected to the reference ground terminal, the power interface VCC of the first active diode circuit IC1 is connected to the reference ground terminal through the third capacitor C3, and the control interface G of the first active diode circuit IC1 is connected to the output terminal of the PFC controller. The drain interface D of a second active diode circuit IC2 is connected to the anode of the fourth diode D4, the source interface S of the second active diode circuit IC2 is connected to the reference ground terminal, the power interface VCC of the second active diode circuit IC2 is connected to the reference ground terminal through the fourth capacitor C4, and the control interface G of the second active diode circuit IC2 is connected to the output terminal of the PFC controller. The cathode of the third diode D3 and the cathode of the fourth diode D4 are connected to the DC voltage output terminal respectively.

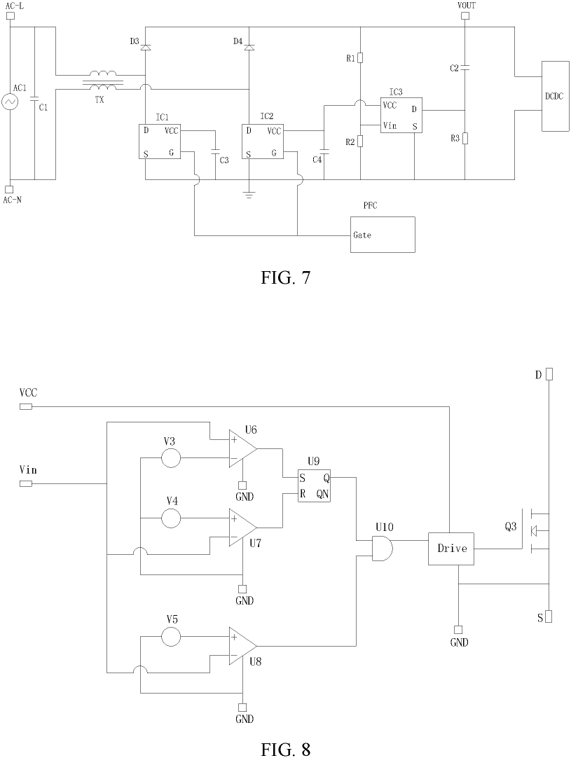

The PFC controller can be a variety of controllers that can realize PFC control in the prior art. It includes two input terminals, one terminal receives the sampling current of the DC voltage output terminal (the IS terminal in FIG. 5), and the other terminal receives the sampling voltage of the DC voltage output terminal (the FB terminal in FIG. 5), the output terminal is the PWM signal (the Gate terminal in FIG. 5). The connections of the PFC controller and its terminals in FIG. 7 and FIG. 10 are the same as that in FIG. 5. In order to simplify the drawing, two input terminals and the connections there between are omitted.

In this solution, the traditional rectifier bridge composed of four diodes is no longer used, but two above-said active diode circuits are used, which can realize the function of converting alternating current into direct current. The active diode circuit has the characteristics of low conduction loss, and reduces the temperature rise of the circuit.

At the same time, the AC-DC power conversion circuit in this solution combines the PFC inductor in the prior art with the common-differential mode inductor TX at the input terminal, and at the same time the switching devices and diodes for PFC are incorporated into the rectifying circuit, i.e. the active diode circuit. Both the function of rectification and the function of receiving PFC control can be realized. The present application reduces separation devices, simplifies the controller of the PFC circuit, and improves the power density of the AC-DC power conversion circuit.

In an embodiment, the timing of the active diode circuit is shown as FIG. 6, at this time the control interface G of the active diode circuit receives the PWM signal. In the figure, IC1-Q1 is the driving signal waveform of the switch transistor Q1 of the first active diode circuit IC1, IC2-Q1 is the driving signal waveform of the first switch transistor Q1 of the second active diode circuit IC2:

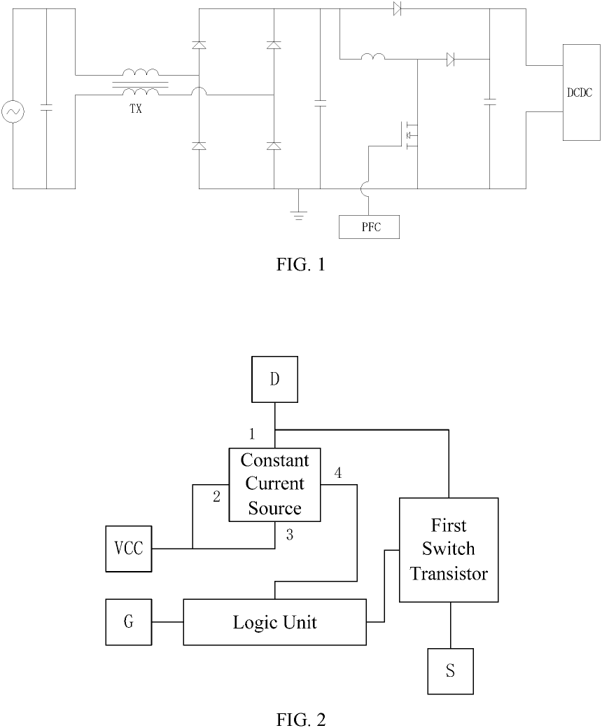

(1) When the VAC is in a positive half cycle, the first active diode circuit IC1 is controlled by the PFC controller, and the first switch transistor Q1 is in a frequent on-off state. The first switch transistor Q1 of IC1 in the PFC circuit is equivalent to that shown in FIG. 1, and two differential mode inductors of the common-differential mode inductor are short circuited. The second active diode circuit IC2 is not controlled by the PFC controller, IC2-Q1 is at a high electric level, and the first switch transistor Q1 of IC2 is in conduction state, the first switch transistor Q1 of IC2 plays a rectifying role.

(2) When VAC is in a negative half cycle, the first active diode circuit IC1 is not controlled by the PFC controller, IC1-Q1 is at a high electric level, the first switch transistor Q1 of IC1 is in conduction state, and the first switch transistor Q1 of IC1 plays a rectifying role. The second active diode circuit IC2 is controlled by the PFC controller, IC2-Q1 is a PWM signal, the first switch transistor Q1 of IC2 is in a frequent on-off state, and the first switch transistor Q1 of IC2 in the PFC circuit is equivalent to the switch transistor in FIG. 1.

Assuming that the PFC controller is working in critical mode, the triangular wave in IAC is the current waveform in the primary coil and secondary coil of the common-differential mode inductor. Of course, by increasing the leakage inductance of TX1, they can also work in continuous mode. VOUT is the output voltage waveform.

As shown in FIG. 7, the AC-DC power conversion circuit also includes a protection circuit IC3, a first resistor R1, a second resistor R2, and a third resistor R3. The first resistor R1 and the second resistor R2 are connected in series between the DC voltage output terminal and the reference ground terminals, and they are configured to divide voltage output from the DC voltage output terminal to obtain the second sampling voltage. The third resistor R3 is connected between the second capacitor C2 and the reference ground terminal. The protection circuit IC3 includes a supply interface VCC, an input interface Vin, the drain interface D of the protection circuit, the source interface S of the protection circuit, and the switch transistor Q3 of the protection circuit. The supply interface VCC of the protection circuit IC3 is connected to the power interface VCC of the first active diode circuit IC1 or the power interface VCC of the second active diode circuit IC2, the input interface Vin of the protection circuit IC3 is configured to receive the second sampling voltage, the drain interface D of the protection circuit IC3 is connected to the common terminal of the second capacitor C2 and the third resistor R3, and the source interface S of the protection circuit IC3 is connected to the reference ground terminal. The drain electrode of the switch transistor Q3 of the protection circuit IC3 is connected to the drain interface D of the protection circuit IC3, and the source electrode of the switch transistor Q3 of the protection circuit IC3 is connected to the source interface S of the protection circuit IC3. The protection circuit IC3 is configured to detect the second sampling voltage. When the second sampling voltage is less than the fourth reference voltage or the second sampling voltage is greater than the fifth reference voltage, the switch transistor Q3 of the protection circuit IC3 is controlled to be in non-conduction state; when the second sampling voltage is greater than the third reference voltage and less than the fifth reference voltage, the switch transistor Q3 of the protection circuit is controlled to be in conduction state, such that the third resistor R3 is short-circuited by the switch transistor Q3 of the protection circuit IC3.

The first resistor R1 and the second resistor R2 form a sampling circuit. The third resistor R3 and the second capacitor C2 are connected in series between the DC voltage output terminal and the reference ground. The third resistor R3 plays the role of current limiting. The protection circuit IC3 collects the voltage at the common terminal of the first resistor R1 and the second resistor R2, and controls the conduction or non-conduction of the switch transistor Q3 of the protection circuit IC3 on the basis of the collected voltage. When the switch transistor Q3 of the protection circuit IC3 is in conduction state, the third resistor R3 is short-circuited , when the switch transistor Q3 of the protection circuit IC3 is in non-conduction state, the third resistor R3 and the second capacitor C2 are connected in series to limit the current, thereby playing the role of protecting the subsequent circuit and the second capacitor C2.

As shown in FIG. 8, the protection circuit IC3 includes a third comparator U6, a fourth comparator U7, a fifth comparator U8, a second RS flip-flop U9, and a second AND gate U10. The third comparator U6 is configured to compare the second sampling voltage with the fourth reference voltage, and output a second comparison signal. The fourth comparator U7 is configured to compare the second sampling voltage with the third reference voltage, and output a third comparison signal. The fifth comparator U8 is configured to compare the second sampling voltage with the fifth reference voltage, and output a first comparison signal. The second RS flip-flop U9 is configured to receive the second comparison signal and the third comparison signal, and output a latch signal. The second AND gate U10 is configured to perform AND logic on the latch signal and the first comparison signal, and output a control signal of the switch transistor Q3 of the protection circuit IC3. The switch transistor Q3 of the protection circuit IC3 is configured to be in conduction or non-conduction state on the basis of the control signal of the switch transistor Q3 of the protection circuit IC3.

By collecting the voltage at the common terminal of the first resistor R1 and the second resistor R2, and combining the fifth reference voltage, the fourth reference voltage and the third reference voltage, the drain electrode and source electrode of the switch transistor Q3 of the protection circuit IC3 is controlled to be in conduction or non-conduction state, thereby realizing whether the third resistor R3 can be connected to the output loop.

In an embodiment, the fourth reference voltage is less than the third reference voltage, and the third reference voltage is less than the fifth reference voltage. The fifth reference voltage, the fourth reference voltage, and the third reference voltage can be provided by correspondingly designing the fifth reference circuit V5, the third reference circuit V3, and the fourth reference circuit V4 according to actual requirements, so as to meet the logic requirements of the circuit.

As shown in FIG. 7, the AC-DC power conversion circuit also includes a DCDC conversion circuit configured for converting a higher DC voltage output from the DC voltage output terminal into a lower DC voltage. The DCDC conversion circuit includes a supply interface and a ground interface. The supply interface of the DCDC conversion circuit is connected to the DC voltage output terminal, and the ground interface of the DCDC conversion circuit is connected to the reference ground terminal.

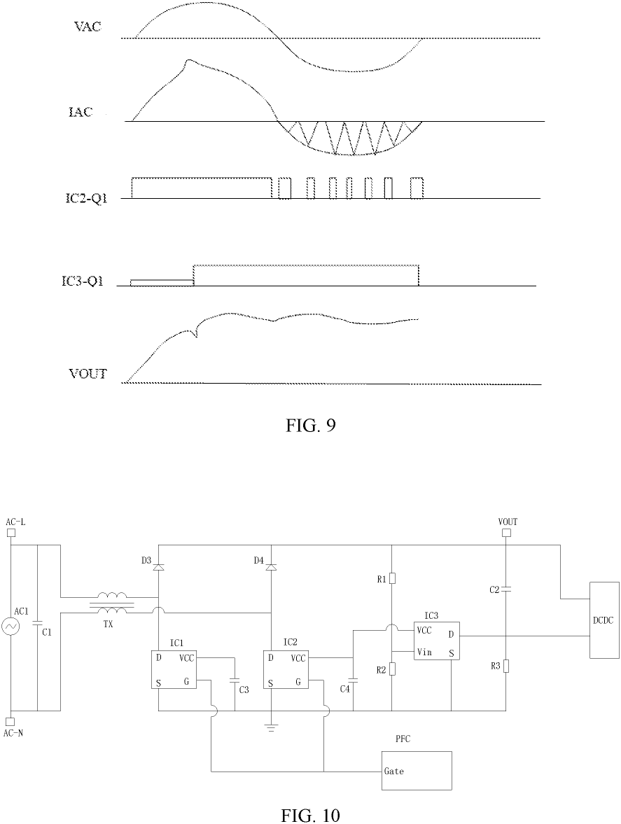

This circuit is provided with a start-up surge protection function. As shown in FIG. 9, it is an operating timing diagram of the start-up surge protection of the AC-DC power conversion circuit, where VAC is the input AC voltage, IAC is the input current waveform, IC2-Q1 is the driving signal waveform of the first switch transistor Q1 in the second active diode circuit IC2, IC3-Q1 is the driving signal waveform of the switch transistor in the protection circuit IC3, and VOUT is the output waveform:

(1) When starting up, there is surge current, the output voltage of the DC voltage output terminal is almost zero, the second sampling voltage received by the protection circuit IC3 is less than the fourth reference voltage, and the second RS flip-flop U9 outputs a low electric level, which passes through the driver Drive to control the switch transistor Q3 of the protection circuit IC3 to be in non-conduction state. At this time, the third resistor R3 and the second capacitor C2 are connected in series in the circuit, and the third resistor R3 limits the charging current of the second capacitor C2, thereby protecting the subsequent circuit.

(2) When charging to a certain stage, the surge current is greatly reduced at this time, the second sampling voltage received by the protection circuit IC3 is between the fifth reference voltage and the fourth reference voltage, and the second RS trigger U9 outputs a low electric level, which passes through the driver Drive to control the switch transistor Q3 of the drive control protection circuit IC3 to be in conduction state, the third resistor R3 is short-circuited, and the start-up surge finishes current limiting.

As shown in FIG. 10, the AC-DC power conversion circuit also includes a DCDC conversion circuit for converting a higher DC voltage output from the DC voltage output terminal into a lower DC voltage. The DCDC conversion circuit includes a supply interface and a ground interface. The supply interface of the DCDC conversion circuit is connected to the DC voltage output terminal, and the ground interface of the DCDC conversion circuit is connected to the common terminal of the second capacitor C2 and the third resistor R3.

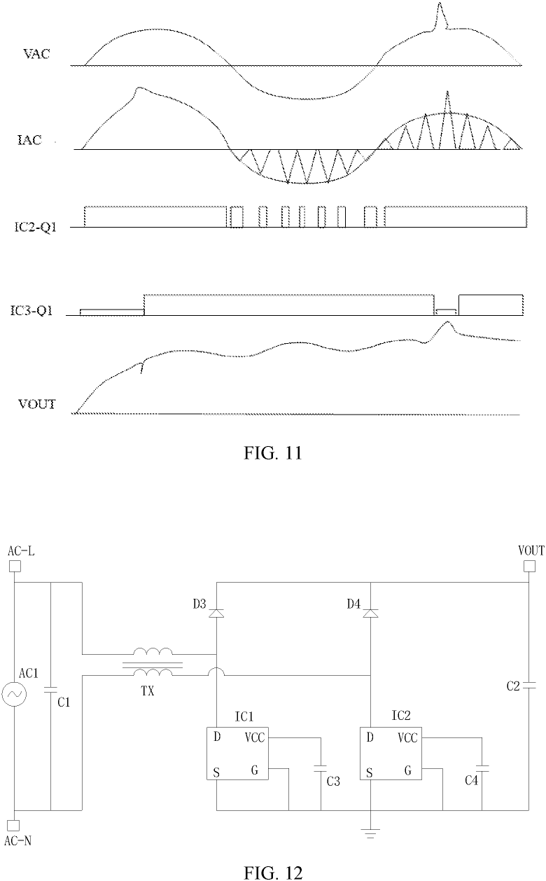

This circuit is provided with the functions of start-up surge protection and overvoltage protection. As shown in FIG. 11, it is the operating timing diagram of the start-up surge and overvoltage protection of the AC-DC power conversion circuit, where VAC is the input AC voltage, IAC is the input current waveform, IC2-Q1 is the driving signal waveform of the first switch transistor Q1 in the second active diode circuit IC2, IC3-Q1 is the driving signal waveform of the switch transistor in the protection circuit IC3, and VOUT is the output waveform:

(1) When starting up, there is surge current, the output voltage of the DC voltage output terminal is almost zero, the second sampling voltage received by the protection circuit IC3 is less than the fourth reference voltage, and the second RS flip-flop U9 outputs a low electric level, which passes through the driver Drive to control the switch transistor Q3 of the protection circuit IC3 to be in non-conduction state. At this time, the third resistor R3 and the second capacitor C2 are connected in series in the circuit, and the third resistor R3 limits the charging current of the second capacitor C2, thereby protecting the subsequent circuit.

(2) When charging to a certain stage, the surge current is greatly reduced at this time, the second sampling voltage received by the protection circuit IC3 is between the fifth reference voltage and the fourth reference voltage, and the second RS trigger U9 outputs a low electric level, which passes through the driver Drive to control the switch transistor Q3 of the drive control protection circuit IC3 to be in conduction state, the third resistor R3 is short-circuited, and the start-up surge finishes current limiting.

(3) When the output voltage of the DC voltage output terminal continues to rise and an overvoltage pulse appears, the second sampling voltage received by the protection circuit IC3 is greater than the fifth reference voltage, the fifth comparator U8 outputs a low electric level, and the second AND gate U10 outputs a low electric level, which passes through the driver Drive to control the switch transistor Q3 of the drive control protection circuit IC3 to be in non-conduction state. The third resistor R3 is connected in series between the reference ground terminal (input ground) and the ground terminal of the DCDC conversion circuit (the ground terminal of the DCDC conversion circuit is the output ground), which plays a role of limiting the amplitude of the overvoltage pulse and protecting the subsequent circuit.

(4) When the overvoltage pulse ends, the second sampling voltage received by the protection circuit IC3 at this time is between the third reference voltage and the fifth reference voltage, returning to step (2) to continue execution, and the overvoltage protection ends.

As shown in FIG. 12, the present application discloses another AC-DC power conversion circuit, including an AC voltage positive input terminal, an AC voltage negative input terminal, a DC voltage output terminal, a reference ground terminal, a first capacitor C1, a second capacitor C2, a third capacitor C3, a fourth capacitor C4, a common-differential mode inductor, a third diode D3, a fourth diode D4, and two above-said active diode circuits. The first capacitor C1 is connected between the AC voltage positive input terminal and the AC voltage negative input terminal. The second capacitor C2 is connected between the DC voltage output terminal and the reference ground terminal. The positive terminal of the primary winding of the common-differential mode inductor is connected to the AC voltage positive input terminal, and the negative terminal of the primary winding of the common-differential mode inductor is connected to the anode of the third diode D3. The positive terminal of the secondary winding of the common-differential mode inductor is connected to the AC voltage negative input terminal, and the negative terminal of the secondary winding of the common-differential mode inductor is connected to the anode of the fourth diode D4. The input interface Vin of the first active diode circuit IC1 is connected to the anode of the third diode D3, the ground interface of the first active diode circuit IC1 is connected to the reference ground terminal, the power interface VCC of the first active diode circuit IC1 is connected to the reference ground terminal through the third capacitor C3, and the control interface G of the first active diode circuit IC1 is connected to the reference ground terminal. The input interface Vin of the second active diode circuit IC2 is connected to the anode of the fourth diode D4, the ground interface of the second active diode circuit IC2 is connected to the reference ground terminal, the power interface VCC of the second active diode circuit IC2 is connected to the reference ground terminal through the fourth capacitor C4, and the control interface G of the second active diode circuit IC2 is connected to the reference ground terminal. The cathode of the third diode D3 and the cathode of the fourth diode D4 are connected to the DC voltage output terminal.

In this solution, the control interfaces G of the first active diode circuit IC1 and the second active diode circuit IC2 are both connected to the reference ground terminal. When the input AC voltage VAC is in a positive half cycle, the first switch transistor Q1 in the first active diode circuit IC1 is in a non-conducing state, and the first switch transistor Q1 in the second active diode circuit IC2 is in conduction state. When the input AC voltage VAC is in a negative half cycle, the first switch transistor Q1 in the first active diode circuit IC1 is in a conducing state, and the first switch transistor Q1 in the second active diode circuit IC2 is in non-conduction state. The first active diode circuit IC1 and the second active diode circuit IC2 cooperate with the first diode D1 and the second diode D2 to form a rectifier bridge, which realizes the function of rectifying the input alternating current.

In this solution, the traditional rectifier bridge composed of four diodes is no longer used, but two above-said active diode circuits are used, which can realize the function of converting alternating current into direct current. The active diode circuit has the characteristics of low conduction loss, and reduces the temperature rise of the circuit.

The above embodiments are only used to explain the technical solutions of the present application, but not to limit the present application. Although the present application has been described in detail with reference to the foregoing embodiments, those of ordinary skill in the art should understand that the technical solutions recorded in the foregoing embodiments can still be modified, or some of the technical features thereof can be equivalently replaced. Such modifications or replacements do not cause the essence of the corresponding technical solutions to deviate from the spirit and scope of the technical solutions of the embodiments of the present application, and shall be included within the protection scope of the present application.

What is claimed is:

1. An active diode circuit, characterized in that, the active diode circuit comprises a power interface, a drain interface, a control interface, a source interface, a logic unit, a constant current source, and a first switch transistor; wherein
the constant current source is provided with a first terminal, a second terminal, a third terminal and a fourth terminal, the first terminal being connected to the drain interface of the active diode circuit, the second terminal and the third terminal both being connected to the power interface, and the fourth terminal being connected to the logic unit; and the constant current source is configured to provide a constant current for the power interface when a voltage input from the drain interface of the active diode circuit charges the power interface;
the logic unit is provided with a first input terminal, a second input terminal and an output terminal, the first input terminal being connected to the fourth terminal of the constant current source, the second input terminal being connected to the control interface, and the output terminal being connected to a gate electrode of the first switch transistor; and the logic unit is configured to:
monitor whether a parasitic body diode of the first switch transistor is in conduction state, that is, whether a voltage difference between a source electrode and a drain electrode of the first switch transistor is greater than a conducting voltage of the body diode,
receive a PWM signal input from the control interface as a control signal for the first switch transistor, if the body diode is in non-conduction state; and
shield the PWM signal input from the control interface and output an electric level signal to control the first switch transistor to be in conduction state, if the body diode is in conduction state; and
the drain electrode of the first switch transistor is connected to the drain interface of the active diode circuit, and the source electrode of the first switch transistor is connected to the source interface of the active diode circuit.

2. The active diode circuit according to claim 1, characterized in that, the constant current source comprises a first diode and a second switch transistor; and the second switch transistor is provided as a depletion-type MOS transistor or JFET transistor; wherein
a drain electrode of the second switch transistor is provided as the first terminal of the constant current source, a source electrode of the second switch transistor is connected to an anode of the first diode and provided as the fourth terminal of the constant current source, and a gate electrode of the second switch transistor is provided as the second terminal of the constant current source; and
a cathode of the first diode is provided as the third terminal of the constant current source.

3. The active diode circuit according to claim 1, characterized in that, the logic unit comprises a first comparator, a second comparator, a first RS flip-flop, and a OR gate, and the source interface of the active diode circuit is connected to a ground potential; wherein
the first comparator is configured to receive a drain voltage of the first switch transistor through the fourth terminal of the constant current source, and compare the drain voltage of the first switch transistor with a first reference voltage to output a first signal;
the second comparator is configured to receive the drain voltage of the first switch transistor through the fourth terminal of the constant current source, and compare the drain voltage of the first switch transistor with a second reference voltage to output a second signal;
the first RS flip-flop is configured to output and latch a third signal on the basis of the first signal and the second signal; and
the OR gate is configured to perform OR logic on the third signal and the PWM signal, and output the control signal for the first switch transistor.

4. The active diode circuit according to claim 3, characterized in that, the logic unit further comprises a first AND gate; wherein
the first AND gate is configured to perform AND logic on a NOT-signal of the third signal and the PWM signal, and output a fourth signal; and
the OR gate is configured to perform OR logic on the third signal and the fourth signal, and output the control signal for the first switch transistor.

5. The active diode circuit according to claim 1, characterized in that, the active diode circuit further comprises a second diode, wherein an anode of the second diode is connected to the control interface, and a cathode of the second diode is connected to the power interface.

6. An AC-DC power conversion circuit, characterized in that, the AC-DC power conversion circuit comprises an AC voltage positive input terminal, an AC voltage negative input terminal, a DC voltage output terminal, a reference ground terminal, a PFC controller, a first capacitor, a second capacitor, a third capacitor, a fourth capacitor, a common-differential mode inductor, a third diode, a fourth diode, and two active diode circuits according to any one of claims 1-5; wherein
the PFC controller is configured to output a PFC control signal on the basis of a sampling voltage of the DC voltage output terminal and a sampling current of the common-differential mode inductor;
the first capacitor is connected in series between the AC voltage positive input terminal and the AC voltage negative input terminal;
the second capacitor is connected in series between the DC voltage output terminal and the reference ground terminal;
the common-differential mode inductor is provided with a primary winding and a secondary winding, a positive terminal of the primary winding is connected to the AC voltage positive input terminal, a negative terminal of the primary winding is connected to an anode of the third diode, a positive terminal of the secondary winding is connected to the AC voltage negative input terminal, a negative terminal of the secondary winding is connected to an anode of the fourth diode, a differential mode inductor of the common-differential mode inductor is configured for energy storage of a PFC circuit, and a common mode inductor of the common-differential mode inductor is configured to eliminate common-mode noise;
a drain interface of a first active diode circuit is connected to the anode of the third diode, a source interface of the first active diode circuit is connected to the reference ground terminal, a power interface of the first active diode circuit is connected to the reference ground terminal through the third capacitor, and a control interface of the first active diode circuit is connected to an output terminal of the PFC controller;
a drain interface of a second active diode circuit is connected to the anode of the fourth diode, a source interface of the second active diode circuit is connected to the reference ground terminal, a power interface of the second active diode circuit is connected to the reference ground terminal through the fourth capacitor, and a control interface of the second active diode circuit is connected to the output terminal of the PFC controller; and
a cathode of the third diode and a cathode of the fourth diode are connected to the DC voltage output terminal.

7. The AC-DC power conversion circuit according to claim 6, characterized in that, the AC-DC power conversion circuit further comprises a protection circuit, a first resistor, a second resistor, and a third resistor; wherein
the first resistor and the second resistor, connected in series between the DC voltage output terminal and the reference ground terminal, are configured to divide voltage output from the DC voltage output terminal to obtain a second sampling voltage;
the third resistor is connected between the second capacitor and the reference ground terminal;
the protection circuit comprises a supply interface, an input interface, a drain interface, a source interface, and a switch transistor; the supply interface of the protection circuit is connected to the power interface of the first active diode circuit or the power interface of the second active diode circuit, the input interface of the protection circuit is configured to receive the second sampling voltage, the drain interface of the protection circuit is connected to a common terminal of the second capacitor and the third resistor, and the source interface of the protection circuit is connected to the reference ground terminal;
a drain electrode of the switch transistor of the protection circuit is connected to the drain interface of the protection circuit, and a source electrode of the switch transistor of the protection circuit is connected to the source interface of the protection circuit; and
the protection circuit is configured to detect the second sampling voltage, when the second sampling voltage is less than a fourth reference voltage or the second sampling voltage is greater than a fifth reference voltage, the switch transistor of the protection circuit is controlled to be in non-conduction state; and when the second sampling voltage is greater than a third reference voltage and less than the fifth reference voltage, the switch transistor of the protection circuit is controlled to be in conduction state.

8. The AC-DC power conversion circuit according to claim 7, characterized in that, the protection circuit further comprises a third comparator, a fourth comparator, a fifth comparator, a second RS flip-flop, and a second AND gate; wherein
the third comparator is configured to compare the second sampling voltage with the fourth reference voltage, and output a second comparison signal;
the fourth comparator is configured to compare the second sampling voltage with the third reference voltage, and output a third comparison signal;
the fifth comparator is configured to compare the second sampling voltage with the fifth reference voltage, and output a first comparison signal;
the second RS flip-flop is configured to receive the second comparison signal and the third comparison signal, and output a latch signal;
the second AND gate is configured to perform AND logic on the latch signal and the first comparison signal, and output a control signal of the switch transistor of the protection circuit; and
the switch transistor of the protection circuit is configured to be in conduction or non-conduction state on the basis of the control signal of the switch transistor of the protection circuit.

9. The AC-DC power conversion circuit according to claim 7, characterized in that, the AC-DC power conversion circuit further comprises a DCDC conversion circuit configured for converting a higher DC voltage output from the DC voltage output terminal into a lower DC voltage, wherein the DCDC conversion circuit comprises a supply interface and a ground interface, the supply interface of the DCDC conversion circuit is connected to the DC voltage output terminal, and the ground interface of the DCDC conversion circuit is connected to the reference ground terminal.

10. The AC-DC power conversion circuit according to claim 7, characterized in that, the AC-DC power conversion circuit further comprises a DCDC conversion circuit configured for converting a higher DC voltage output from the DC voltage output terminal into a lower DC voltage, wherein the DCDC conversion circuit comprises a supply interface and a ground interface, the supply interface of the DCDC conversion circuit is connected to the DC voltage output terminal, and the ground interface of the DCDC conversion circuit is connected to the common terminal of the second capacitor and the third resistor.

11. An AC-DC power conversion circuit, characterized in that, the AC-DC power conversion circuit comprises an AC voltage positive input terminal, an AC voltage negative input terminal, a DC voltage output terminal, a reference ground terminal, a first capacitor, a second capacitor, a third capacitor, a fourth capacitor, a common-differential mode inductor, a third diode, a fourth diode, and two active diode circuits according to any one of claims 1-5; wherein
the first capacitor is connected between the AC voltage positive input terminal and the AC voltage negative input terminal;
the second capacitor is connected between the DC voltage output terminal and the reference ground terminal;
the common-differential mode inductor is provided with a primary winding and a secondary winding; a positive terminal of the primary winding is connected to the AC voltage positive input terminal, a negative terminal of the primary winding is connected to an anode of the third diode; a positive terminal of the secondary winding is connected to the AC voltage negative input terminal, and a negative terminal of the secondary winding is connected to an anode of the fourth diode;
an input interface of a first active diode circuit is connected to the anode of the third diode, a ground interface of the first active diode circuit is connected to the reference ground terminal, a power interface of the first active diode circuit is connected to the reference ground terminal through the third capacitor, and a control interface of the first active diode circuit is connected to the reference ground terminal;
an input interface of a second active diode circuit is connected to the anode of the fourth diode, a ground interface of the second active diode circuit is connected to the reference ground terminal, a power interface of the second active diode circuit is connected to the reference ground terminal through the fourth capacitor, and a control interface of the second active diode circuit is connected to the reference ground terminal; and
a cathode of the third diode and a cathode of the fourth diode are connected to the DC voltage output terminal.
